(19) United States
(12) Patent Application Publication
(10) Pub. No.: US 2026/0090333 A1
(43) Pub. Date: Mar. 26, 2026

(54) SEMICONDUCTOR DEVICE AND METHOD OF COMMUNICATION BY SEMICONDUCTOR DEVICE

(71) Applicant: Taiwan Semiconductor Manufacturing Company, Ltd., Hsinchu (TW)

(72) Inventors: Shenggao LI, Hsinchu (TW); Wen-Hung HUANG, Hsinchu (TW)

(73) Assignee: Taiwan Semiconductor Manufacturing Company, Ltd., Hsinchu (TW)

(21) Appl. No.: 19/033,773

(22) Filed: Jan. 22, 2025

Related U.S. Application Data
(60) Provisional application No. 63/697,878, filed on Sep. 23, 2024.

(51) Int. Cl. H01L 21/66

(52) U.S. Cl. CPC H10P 74/203

(57) ABSTRACT

In one or more aspects, a semiconductor device includes a processing circuitry and N signal paths corresponding to N communication lanes. The processing circuitry is configured to obtain lane defect information indicating L defective lanes or (N−L) functional lanes among the N communication lanes; apply a remapping configuration corresponding to a mapping relationship between a flow control unit (flit) protocol format having M rows of N data units and a flit reassemble format having (M+R) rows of (N−L) data units; and obtain a target flit in the flit protocol format and transmit data units of the target flit through (N−L) functional lanes based on the flit reassemble format, or receive the data units of the target flit through the (N−L) functional lanes based on the flit reassemble format and obtain the target flit in the flit protocol format.

### PRIORITY CLAIM AND CROSS-REFERENCE

This patent application claims the benefit of U.S. Provisional Patent Application No. 63/697,878 filed on Sep. 23, 2024, the entire disclosure of which is hereby incorporated by reference.

### BACKGROUND

The integrated circuit (IC) industry has experienced rapid growth. Technological advances in IC materials and design have produced generations of IC devices. Each generation has smaller and more complex circuits than the previous generation. For example, in the course of IC evolution, functional density (i.e., the number of interconnected devices per chip area) has generally increased while geometric size (i.e., the smallest component (or line) that can be created using a fabrication process) has decreased. This scaling-down process typically provides benefits by increasing production efficiency and lowering associated costs. Accordingly, these advances have increased the complexity of processing and manufacturing IC devices.

In some applications, a semiconductor device (e.g., an IC device) includes multiple semiconductor dies or circuitry blocks encapsulated within an IC package. Different dies or circuitry blocks may be designed by different IC design companies and/or manufactured based on different manufacturing technologies (or nodes). As such, the overall design of the semiconductor device may be divided into smaller projects in order to expedite the design process and/or to have each die optimized based on its corresponding functionality. In some applications, the semiconductor dies circuitry blocks in a semiconductor device are configured to work together based on transmitting and receiving data from one another through correspondence die-to-die communication paths. When a communication path for such die-to-die communication within a semiconductor device becomes defective after the semiconductor device is installed into an electronic device, opening the IC package to repair the defective communication path is not feasible. In some applications such as in a motor vehicle, the defective communication path will cause safety or reliability concerns, affect the normal operation of the motor vehicle, and/or potentially cause severe loss of data or fatal accidents.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a semiconductor device, according to various embodiments.

FIG. 2 is a protocol stack diagram of a die-to-die interconnect protocol example, according to various embodiments.

FIG. 3 is a functional block diagram of a physical layer circuitry example, according to various embodiments.

FIG. 4 is a process flow diagram of various operations performed by a first processing circuitry and a second processing circuitry, according to various embodiments.

FIG. 5A is a diagram of a flow control unit (flit) protocol format example based on a Universal Chiplet Interconnect Express (UCIe) standard, according to various embodiments.

FIG. 5B is a diagram of a flit reassemble format example derived from the flit protocol format of FIG. 5A based on a first remapping scheme, according to various embodiments.

FIG. 5C is a diagram of a flit reassemble format example derived from the flit protocol format of FIG. 5A based on a second remapping scheme, according to various embodiments.

FIG. 6A is a block diagram of a set of shift registers for converting a flit in the flit protocol format in FIG. 5A to data units in the flit reassemble format example in FIG. 5B, according to various embodiments.

FIG. 6B is a block diagram of a control logic of the set of shift registers in FIG. 6A and a component register example of the set of shift registers in FIG. 6A, according to various embodiments.

FIG. 7A is a diagram of repair registers for storing data units of a target flit that correspond to the defective lanes, according to various embodiments.

FIGS. 7B and 7C are diagrams of various multiplexer examples usable in conjunction with the repair registers in FIG. 7A for converting a flit in the flit protocol format in FIG. 5A to data units in the flit reassemble format example in FIG. 5C, according to various embodiments.

FIG. 8 is a flowchart of a method of communication, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

In some embodiments, the data communications between two semiconductor dies or circuitry blocks are implemented based on communication lanes, where data units (e.g., bytes) of a flow control unit (flit) are transmitted in one or more sessions or cycles (e.g., rows) over a plurality of lanes for each transmission session. One communication standard example for such applications is a Universal Chiplet Interconnect Express (UCIe) standard. In some embodiments, the communication lanes are configured with redundant lanes, which can be used in a case that one or more of the communication lanes are defective.

In some embodiments, the defective lanes are identified and the data width (e.g., the number of lanes for the transmission) is dynamically adjustable. According to one or more embodiments of the disclosure, the reliability of data transmission is protected based on dynamically adjusting the flit format for die-to-die communication using fewer communication lanes to avoid the defective communication lanes. In some embodiments, the communication based on dynamically adjusting the flit format to use fewer communication lanes as presented in this disclosure applies not only to die-to-die communications but also other types of multi-lane communication between dies, processing circuitry blocks, IC devices, or the like. In some embodiments, the communication based on dynamically adjusting the flit format to use fewer communication lanes as presented in this disclosure is usable independently or jointly with the lane repair based on redundant lanes.

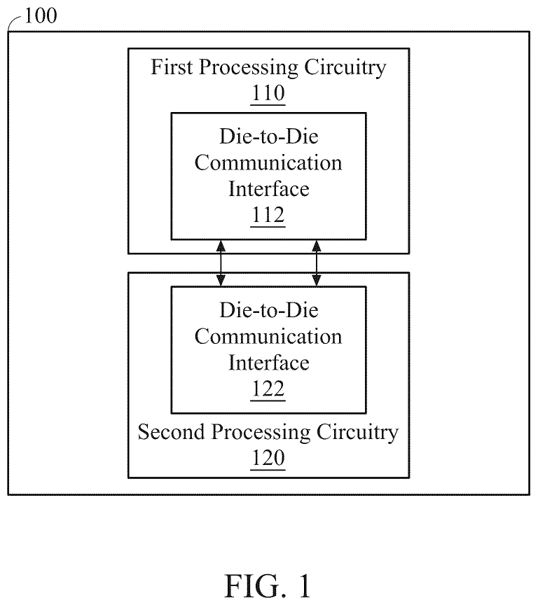

FIG. 1 is a block diagram of a semiconductor device 100, according to various embodiments. In some embodiments, semiconductor device 100 is an integrated circuit (IC) device that includes components encapsulated in an IC package. Semiconductor device 100 includes a first processing circuitry 110 and a second processing circuitry 120. In some embodiments, first processing circuitry 110 is a semiconductor die or a processing circuitry block in semiconductor device 100. In some embodiments, second processing circuitry 120 is another semiconductor die or another processing circuitry block in semiconductor device 100. In some embodiments, semiconductor device 100 includes one or more additional dies or circuitry blocks, which are not depicted in FIG. 1. In some embodiments, first processing circuitry 110 and second processing circuitry 120 inside the IC package of semiconductor device 100 are semiconductor dies and are also referred to as “chiplets.” In some embodiments, first processing circuitry 110 and second processing circuitry 120 are a first die and a second die and are disposed and electrically coupled with each other based on a 2 dimensional (2D) packaging technology (e.g., the first die and the second die mounted on a shared packaging substrate), a 2.5 dimensional (2.5D) packaging technology (e.g., the first die and the second die mounted on a shared interposer that is on a packaging substrate), or a 3 dimensional (3D) packaging technology (e.g., the first die and the second die stacked one over the other and then mounted on a packaging substrate with or without an interposer).

In some embodiments, first processing circuitry 110 and second processing circuitry 120 correspond to semiconductor dies with digital circuitry, analog circuitry, mixed-mode circuitry, and/or memory formed thereon. In some embodiments, each one of first processing circuitry 110 and second processing circuitry 120 corresponds to one or more central processing units (CPUs), application processors (APs), system on chips (SOCs), application specific integrated circuits (ASICs), dynamic random access memory (DRAM) dies, static random access memory (SRAM) dies, micro-electro-mechanical system (MEMS) dies, or the like.

In the example of FIG. 1, first processing circuitry 110 includes a die-to-die communication interface 112, and second processing circuitry 120 includes a die-to-die communication interface 122. In some embodiments, first processing circuitry 110 and second processing circuitry 120 are configured to communicate with each other within semiconductor device 100 through die-to-die communication interface 112 and die-to-die communication interface 122. In some embodiments, the communication between die-to-die communication interface 112 and die-to-die communication interface 122 is based on a die-to-die interconnect protocol, such as a protocol based on a Universal Chiplet Interconnect Express (UCIe) standard, a protocol based on a Bunch of Wires (BoW) standard, a proprietary protocol, or the like.

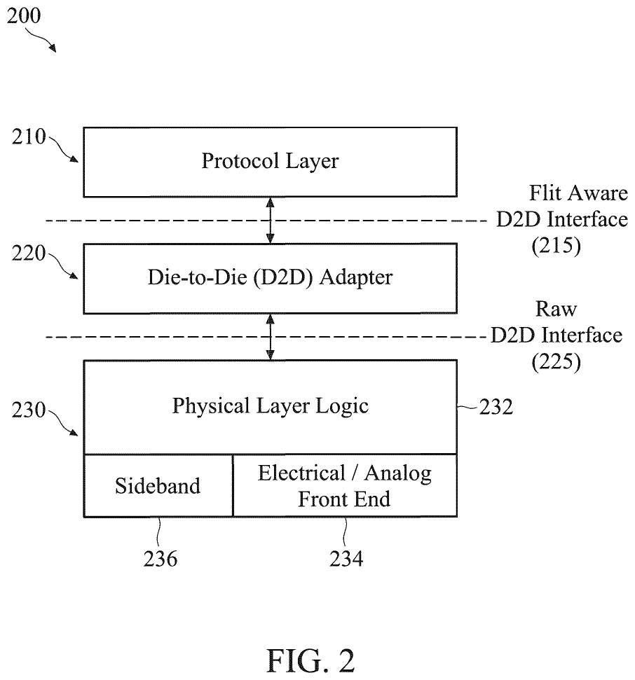

FIG. 2 is a protocol stack diagram of a die-to-die interconnect protocol example 200, according to various embodiments. In some embodiments, die-to-die interconnect protocol example 200 is illustrated as a non-limiting example. In some embodiments, a die-to-die interconnect protocol corresponds to a protocol stack that does not include all the layers in the protocol stack diagram. In some embodiments, a die-to-die interconnect protocol corresponds to a protocol stack that includes one or more layers in addition to those in the protocol stack diagram. In some embodiments, die-to-die interconnect protocol 200 corresponds to a die-to-die interconnect protocol based on UCIe as a non-limiting example. In some embodiments, die-to-die interconnect protocol 200 is usable for implementing communication between dies in an IC device. In some embodiments, die-to-die interconnect protocol 200 is usable for implementing communication between processing circuit blocks in a die or between IC devices.

In FIG. 2, die-to-die interconnect protocol 200 includes a protocol layer 210, a die-to-die (D2D) adapter 220, and a physical layer 230. Protocol layer 210 and D2D adapter 220 are configured to communicate with each other through a flow control unit (flit) aware D2D interface 215. D2D adapter 220 and physical layer 230 are configured to communicate with each other through a raw D2D interface 225. In some embodiments, protocol layer 210 corresponds to a communication protocol based on a Peripheral Component Interconnect Express (PCIe) standard, a Compute Express Link (CXL) standard, or a proprietary communication standard.

In FIG. 2, D2D adapter 220 corresponds to operations to bridge the data to/from protocol layer 210 and physical layer 230, such that the physical layer 230 is capable of working with different types of communication protocol at protocol layer 210. In some embodiments, D2D adapter 220 is configured to manage the data transmission between protocol layer 210 and physical layer 230, including data format conversion, link state management, error correction management, retry management, parameter negotiation, arbitration, and/or multiplexing among two or more protocols supported by protocol layer 210, or the like.

In some embodiments, a semiconductor die includes a protocol circuitry configured to perform operations of D2D adapter 220 and protocol layer 210. In some embodiments, a die-to-die interconnect protocol does not define a D2D adapter and instead defines a protocol layer incorporating the operations of D2D adapter 220 and protocol layer 210 in FIG. 2.

In some embodiments, physical layer 230 is configured to transmit and receive electrical signals for execution of the data transmission with another semiconductor die or processing circuitry block via a plurality of signal paths. In some embodiments, each signal path is configured to carry a data unit (e.g., a byte) of information and is referred to as a “communication lane” or a “lane.” In FIG. 2, physical layer 230 includes a physical layer logic 232, an electrical/analog front end 234, and a sideband 236. In some embodiments, electrical/analog front end 234 is configured to transmit and receive flits to and from another semiconductor die or processing circuitry block; and sideband 236 is configured to transmit and receive control information to and from another semiconductor die or processing circuitry block. In some embodiments, electrical/analog front end 234 and sideband 236 include conductive terminals (e.g., bumps), transmitters and/or receivers coupled to the conductive terminals, and multiplexers coupled to the transmitters and/or receivers for selectively rearranging the pin assignment of the conductive terminals for repairing one or more defective lanes.

In some embodiments, based on UCIe standard, electrical/analog front end 234 is configured to communicate over 64 data lanes for transmission, 64 data lanes for reception, 1 data valid lane for transmission, 1 data valid lane for reception, 2 clock lanes for differential clock signals for transmission, 2 clock lanes for differential clock signals for reception, 1 track signal laned for transmission, and 1 track signal lane for reception. In some embodiments, based on UCIe standard, electrical/analog front end 234 is further configured to communicate over redundant lanes for lane repair, if needed, including 4 redundant data lanes for transmission, 4 redundant data lanes for reception, 1 redundant data valid lane for transmission, 1 redundant data valid lane for reception, 1 redundant clock lane for transmission, and 1 redundant clock lane for reception.

In some embodiments, based on UCIe standard, sideband 236 is configured to communicate over 1 data lane for transmission, 1 data lane for reception, 1 clock lane for transmission, and 1 clock lane for reception. In some embodiments, based on UCIe standard, sideband 236 is further configured to communicate over redundant lanes for lane repair, if needed, including 1 redundant data lane for transmission, 1 redundant data lane for reception, 1 redundant clock lane for transmission, and 1 redundant clock lane for reception.

In some embodiments, physical layer logic 232 is configured to coordinate operations of electrical/analog front end 234 and sideband 236 for operations including link initialization, link training, lane repair, lane reversal, scrambling or de-scrambling of data, sideband training, sideband transfer, or the like. In some embodiments, redundancy is implemented based on configuring multiple to skip the defective lane and repurpose/remap other functional lanes together with one or more redundant lanes to make up for the deficiency of the defective lanes. In some embodiments, a sequence of shuffling multiplexer settings is needed to shift or redirect data paths to the remanned lanes.

However, there are cases where lane repair based on redundant lanes is not possible. In some examples, a semiconductor die is implemented with no redundant lane for lane repair. In some examples, a semiconductor die has already used all available redundant lanes for lane repair and still has one or more defective lanes. In such scenarios, according to one or more embodiments of the disclosure, the reliability of data transmission is still protected based on dynamically adjusting the flit format for die-to-die communication using fewer communication lanes to avoid the defective communication lanes. In some embodiments, the communication based on dynamically adjusting the flit format to use fewer communication lanes as presented in this disclosure applies not only to die-to-die communications but also any types of multi-lane communications between dies, processing circuitry blocks, IC devices, or the like. In some embodiments, the communication based on dynamically adjusting the flit format to use fewer communication lanes as presented in this disclosure is usable independently or jointly with the lane repair based on redundant lanes.

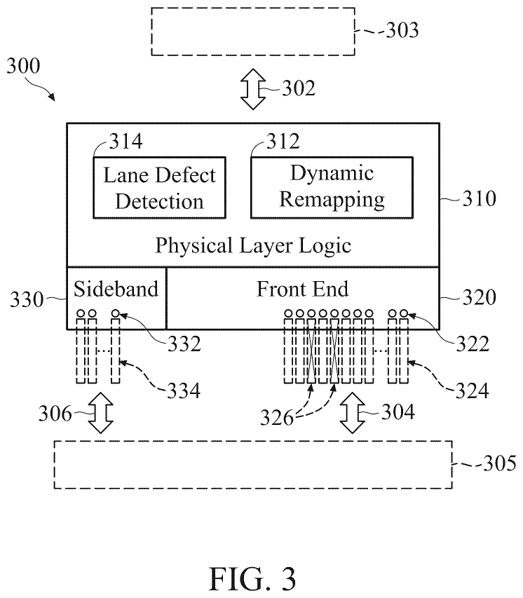

FIG. 3 is a functional block diagram of a physical layer circuitry example 300, according to various embodiments. In some embodiments, physical layer circuitry 300 is configured to implement the operations of physical layer 230 in FIG. 2. In some embodiments, physical layer circuitry 300 is part of a processing circuitry (e.g., a semiconductor die) and is configured to communicate with another processing circuitry (e.g., another semiconductor die) based on a die-to-die interconnect protocol as illustrated in FIG. 2.

In FIG. 3, physical layer circuitry 300 includes a physical layer logic circuitry 310 corresponding to physical layer logic 232, a front end circuitry 320 corresponding to electrical/analog front end 234, and a sideband circuitry 330 corresponding to sideband 236. In FIG. 3, physical layer logic circuitry 310 is configured to communicate (indicated by arrow 302) with a protocol circuitry 303 (e.g., corresponding to protocol layer 210 in FIG. 2, directly or indirectly through D2D adapter 220).

In FIG. 3, front end circuitry 320 includes a plurality of signal paths coupled to a plurality of conductive terminals (e.g., bumps) 322 and corresponding to a plurality of data lanes, clock lanes, and signaling lanes (collectively communication lanes 324) for die-to-die communication. In some embodiments, communication lanes 324 include at least N communication lanes as data lanes, where N is a positive integer. In some embodiments, front end circuitry 320 is configured to communicate (indicated by arrow 304) with another processing circuitry 305 (e.g., another semiconductor die) through the data lanes and associated clock lanes and signaling lanes.

In FIG. 3, sideband circuitry 330 also includes a plurality of signal paths coupled to a plurality of conductive terminals (e.g., bumps) 332 and corresponding to one or more sideband data lanes, sideband clock lanes, and sideband signaling lanes (collectively sideband communication lanes 334) for control information associated with the die-to-die communication through front end circuitry 320. In some embodiments, sideband circuitry 330 is configured as a control interface to communicate (indicated by arrow 306) with another processing circuitry 305 through the one or more sideband data lanes and associated sideband clock lanes and sideband signaling lanes.

In some embodiments, the data units of a flit are arranged in a flit protocol format for transmission or reception. In some embodiments, the data units of a flit are arranged into N columns corresponding to the N communication lanes, and M rows corresponding to M transmission or reception sessions or cycles performed by the N communication lanes. In some embodiments, each data unit corresponds to a byte.

In FIG. 3, physical layer logic circuitry 310 includes a dynamic remapping circuitry 312 and a lane defect detection circuitry 314. In some embodiments, dynamic remapping circuitry 312 is coupled to the protocol processing circuitry 303, front end circuitry 320, and communication lanes 324 through front end circuitry 320, sideband circuitry 330, and sideband communication lanes through sideband circuitry 330. In some embodiments, dynamic remapping circuitry 312 is configured to obtain lane defect information indicating L defective lanes among the N communication lanes, or indicating (N−L) functional lanes among the N communication lanes, where L is zero or a positive integer. In this example, two communications lanes 326 are defective (e.g., L=2 in FIG. 3). In some embodiments, dynamic remapping circuitry 312 is configured to obtain the lane defect information from lane defect detection circuitry 314. In some embodiments, the lane defect information is generated by lane defect detection circuitry 314 or received by lane defect detection circuitry 314 from another processing circuitry 305 through the control interface (e.g., sideband circuitry 330) over sideband communication lanes 334.

In some embodiments, based on L being greater than zero and based on the lane defect information, dynamic remapping circuitry 312 applies a remapping configuration corresponding to a mapping relationship between a flit protocol format having M rows of N data units and a flit reassemble format having (M+R) rows of (N−L) data units, where M is a positive integer, and R is a positive integer representing the extra rows for lane repair. In some embodiments, N represents the number of communication lanes per transmission session/cycle based on the flit protocol format, and M represents the number of rows or transmission sessions/cycles based on the flit protocol format. In some embodiments, a data unit is transmitted per communication lane per transmission session/cycle. In some embodiments, R represents the number of extra rows, which corresponds to the number of extra transmission sessions/cycles usable to make up for the deficiencies in transmission capacity as a result of having the L defective lanes. In some embodiments, each one of the data units corresponds to a byte, N ranges from 32 to 128, M ranges from 1 to 8, and R ranges from 1 to 4. In some embodiments, based on the UCIe standard, each one of the data units corresponds to a byte, N is 64, M is 4, and R is 1.

In some embodiments, based on L being greater than zero and based on the remapping configuration, dynamic remapping circuitry 312 is configured to obtain a target flit in the flit protocol format and transmit the data units of the target flit to another processing circuitry 305 through the (N−L) functional lanes based on the flit reassemble format. In some embodiments, based on L being greater than zero and based on the remapping configuration, dynamic remapping circuitry 312 is configured to receive the data units of the target flit from another processing circuitry 305 through the (N−L) functional lanes based on the flit reassemble format and obtain the target flit for the protocol circuitry 303 based on the flit protocol format. In some embodiments, based on the UCIe standard, the target flit corresponds to a flit of 256 bytes.

In some embodiments according to a first remapping scheme, the mapping relationship corresponds to sequentially mapping N data units per row, M rows in total, in the flit protocol format to (N−L) data units per row, (M+R) rows in total, in the flit reassemble format. In some embodiments according to a second remapping scheme, the mapping relationship corresponds to mapping (N−L) data units per row, M rows in total, in the flit protocol format that correspond to the (N−L) functional lanes to (N−L) data units per row, M rows in total, in the flit reassemble format based on original row and lane assignments in the flit protocol format; and mapping M×L data units in the flit protocol format that corresponds to the L defective lanes to up to R extra rows in the flit reassemble format.

In some embodiments, based on L being zero indicating that there are no defective lanes, the transmission is executed based on the flit protocol format without any remapping configuration.

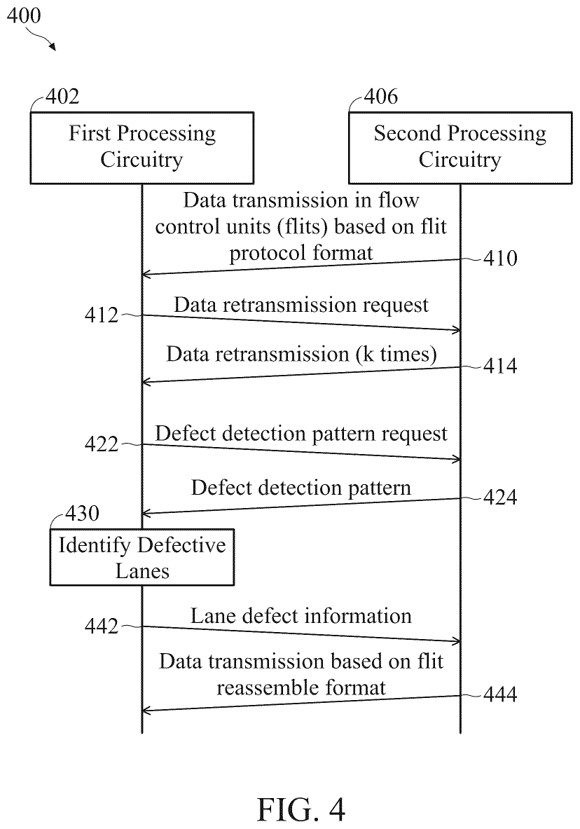

FIG. 4 is a process flow diagram 400 of various operations performed by a first processing circuitry 402 and a second processing circuitry 406, according to various embodiments. In some embodiments, one of first processing circuitry 402 and second processing circuitry 406 corresponds to a semiconductor die or a processing circuitry incorporating physical layer circuitry 300 and protocol circuitry 303 in FIG. 3. In some embodiments, the other one of first processing circuitry 402 and second processing circuitry 406 corresponds to a semiconductor die or a processing circuitry incorporating processing circuitry 305 in FIG. 3.

In FIG. 4, at stage 410, first processing circuitry 402 receives data transmission from second processing circuitry 406 based on a die-to-die interconnect protocol. In this example, the data transmission is performed in flits arranged based on a flit protocol format and over N communication lanes. In some embodiments, first processing circuitry 402 observes that some of the flits from stage 410 are corrupted or not decodable. As such, at stage 412, first processing circuitry 402 sends a data retransmission request to second processing circuitry 406 requesting for retransmission of the corrupted flits. At stage 414, in response to the data retransmission request, second processing circuitry 406 performs data retransmission based on the die-to-die interconnect protocol. In some embodiments, the data retransmission at stage 414 is performed at least k times (k being a positive integer) consistent with the die-to-die interconnect protocol.

In FIG. 4, after stage 414, first processing circuitry 402 is still unable to receive or decode all the corrupted flits despite the retransmission at stage 414. At stage 422, first processing circuitry 402 then transmits a defect detection pattern request to second processing circuitry 406 requesting transmission of a defect detection pattern. In some embodiments, the defect detection pattern includes one or more test flits for identifying the defective one or more communication lanes among the N communication lanes. At stage 424, second processing circuit 406 transmits one or more test flits to first processing circuitry 402 through the N communication lanes. Also, at stage 424 first processing circuitry 402 receives the one or more test flits from second processing circuitry 406 through the N communication lanes.

At stage 430, first processing circuitry 402 identifies L defective lanes or (N−L) functional lanes among the N communication lanes based on reception of the one or more test flits. At stage 442, first processing circuitry 402 transmits to second processing circuitry 406 through a control interface (e.g., sideband circuitry 330 and sideband communication lanes 334) of first processing circuitry 402, the lane defect information. Also, second processing circuitry 406 receives, from first processing circuitry 402 through a control interface of second processing circuitry 406, the lane defect information. In some embodiments, the lane defect information indicates the L defective lanes or the (N−L) functional lanes.

At stage 444, first processing circuitry 402 and second processing circuitry 406 perform data transmission based on a flit reassemble format that is determined according to the lane defect information as illustrated with reference to FIG. 3.

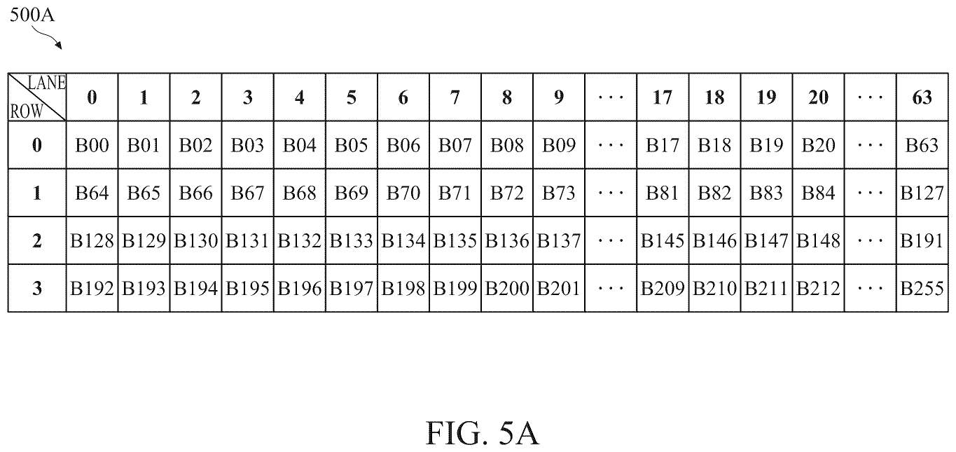

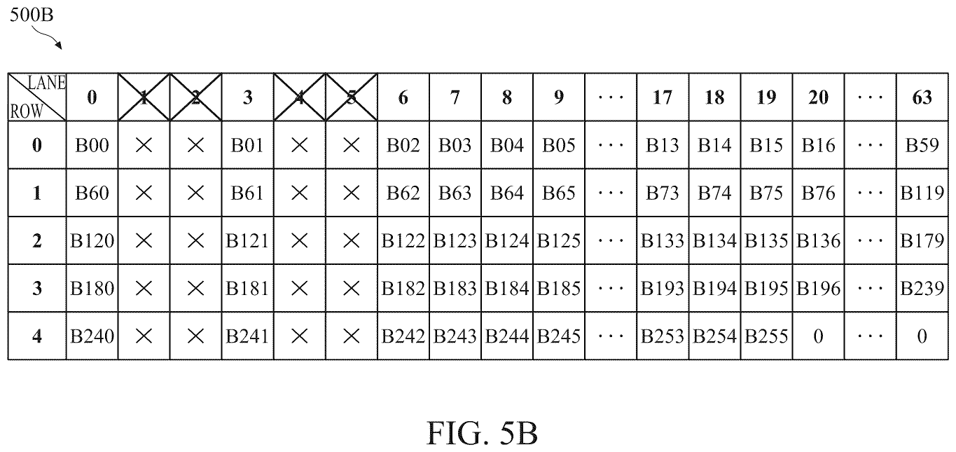

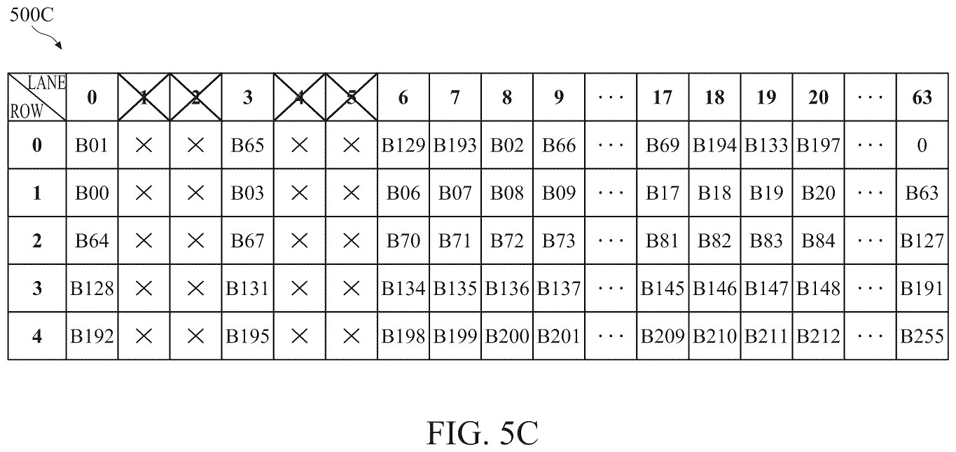

FIG. 5A is a diagram of a flit protocol format example 500A based on a UCIe standard, according to various embodiments. In FIG. 5A, flit protocol format 500A includes 256 data units (e.g., bytes, from B00 to B255) arranged into 4 rows and 64 columns. In FIG. 5A, each column of data units corresponds to the data units to be transmitted or received by a corresponding communication lane. For example, data units B00, B64, B128, and B192 according to flit protocol format 500A are to be transmitted or received via communication lane 0; data units B01, B65, B129, and B193 according to the flit protocol format 500A are to be transmitted or received via communication lane 1; data units B02, B66, B130, and B194 according to the flit protocol format 500A are to be transmitted or received via communication lane 2; and data units B63, B127, B191, and B255 according to the flit protocol format 500A are to be transmitted or received via communication lane 63.

FIG. 5B is a diagram of a flit reassemble format example 500B derived from the flit protocol format 500A of FIG. 5A based on a first remapping scheme, according to various embodiments. In FIG. 5B, communication lanes 1, 2, 4, and 5 are identified as defective lanes (labeled with “x” marks). According to a first remapping scheme, the data units are to be reassembled based on sequentially shifting the data units of a target flit to the functional lanes and skipping the defective lanes. For example, compared to the flit protocol format 500A, data unit B01 is shifted from communication lane 1 at row 0 to communication lane 3 at row 0 in flit reassemble format 500B; and data unit B02 is shifted from communication lane 2 at row 0 to communication lane 6 at row 0. As such, at least 16 data units B240-B255 are shifted from row 3 to an extra row (row 4 in FIG. 5C) for lane repair.

FIG. 5C is a diagram of a flit reassemble format example 500C derived from the flit protocol format 500A of FIG. 5A based on a second remapping scheme, according to various embodiments. In FIG. 5C, communication lanes 1, 2, 4, and 5 are identified as defective lanes (labeled with “x” marks). According to a second remapping scheme, the data units are to be reassembled based on moving the data units assigned to the defective lanes to one or more extra rows (e.g., row 0 in FIG. 5C). For example, compared to the flit protocol format 500A, data units in all the functional lanes are arranged based on the original row and lane assignments in the flit protocol format (e.g., all the row assignments shifted by 1 without changing the row sequence, and the lane assignments kept the same) in flit reassemble format 500C. Also, the skipped data units (e.g., data units corresponding to rows 0-3, lanes 1, 2, 4, and 5, in flit protocol format 500A) are added to a new row (e.g., row 0 in FIG. 5C). In this non-limiting example, the extra row is transmitted or received before the rows based on the original row and lane assignments. In some embodiments, one or more extra rows for lane repair are transmitted or received before or after the rows based on the original row and lane assignments.

In some embodiments, as a generalized description for the first remapping scheme in FIG. 5B and the second remapping scheme in FIG. 5C, a flit protocol format having M rows of N data units is converted to a flit reassemble format having (M+R) rows of (N−L) data units, where L indicates the number of defective lanes, and R represents the number of extra lanes. In FIG. 5B, N is 64, M is 4, and R is 1. In some embodiments, N ranges from 32 to 128, M ranges from 1 to 8, and R ranges from 1 to 4.

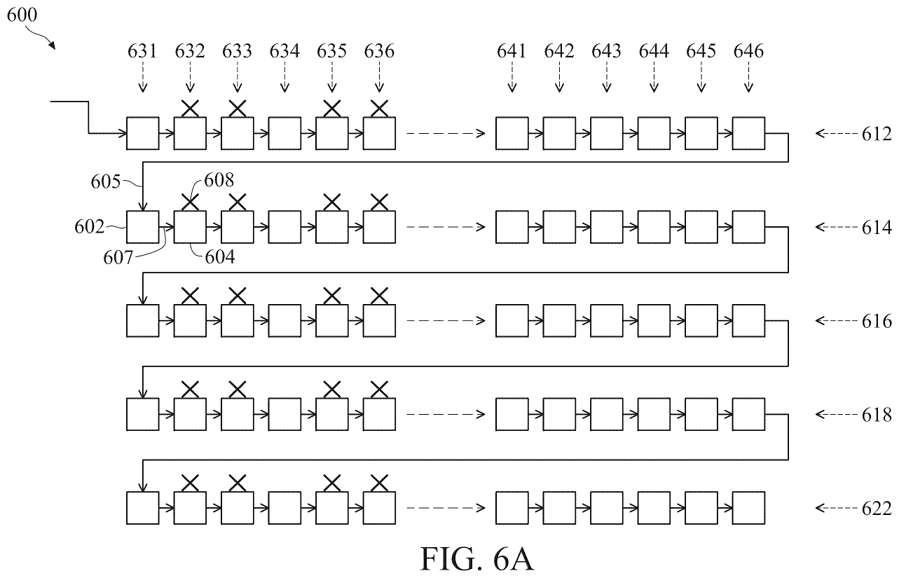

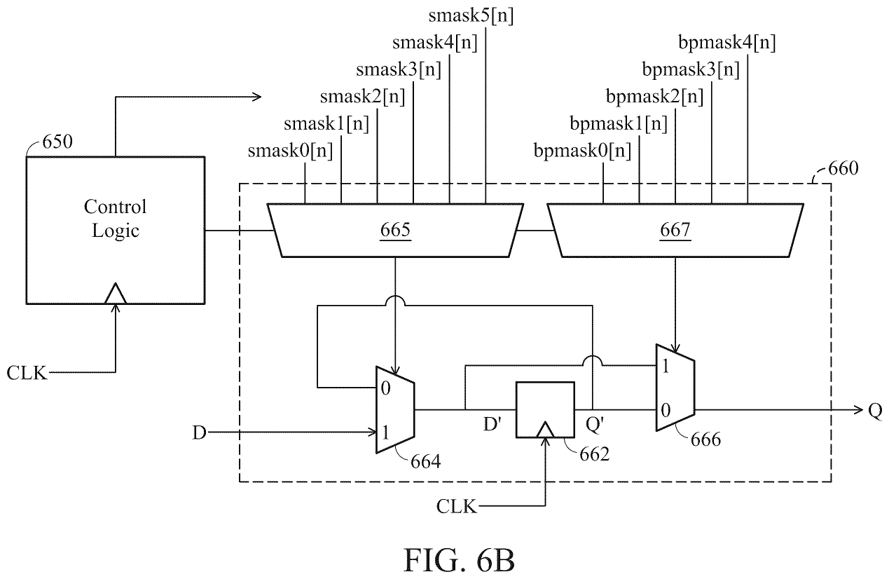

FIG. 6A is a block diagram of a set of shift registers 600 for converting a flit in flit protocol format 500A in FIG. 5A to data units in flit reassemble format example 500B in FIG. 5B, according to various embodiments. In some embodiments, the set of shift registers 600 is incorporated in dynamic remapping circuitry 312 in FIG. 3, or incorporated in physical layer logic circuitry 310 in FIG. 3 and accessible by dynamic remapping circuitry 312.

In FIG. 6A, each square box (e.g., indicated by reference numbers 602 and 604 as examples) represents a component register configured to store a bit. In some embodiments, for a communication lane configured to transmit a data unit that is a byte (e.g., 8 bits) at a transmission session, a flit is stored in 8 sets of shift registers, each set is based on the set of shift registers 600 as a non-limiting example.

In FIG. 6A, the arrows leading to or leaving each one of the component registers (e.g., indicated by reference numbers 605 and 607 as examples) represent the data shifting direction among the component registers. In FIG. 6A, the cross mark (e.g., indicated by reference number 608 as an example) indicates that the corresponding component register is mapped to a defective lane. Moreover, the set of shift registers 600 usable for converting a flit in flit protocol format 500A to data units in flit reassemble format example 500B are arranged into 5 rows (corresponding to rows 0, 1, 2, 3, and 4 in FIG. 5B and indicated by reference numbers 612, 614, 616, 618, and 622, respectively) and 64 columns (corresponding 64 lanes in FIG. 5B and indicated by, e.g., reference numbers 631-636 and 641-646). In some embodiments, dynamic remapping circuitry 312 in FIG. 3 prepare the data units of a target flit in a number of sets of shift registers, where the number is determined based on a number of bits per data unit of the target flit. In some embodiments, physical layer logic circuitry 310 in FIG. 3 transmits the data units stored in one row of the sets of shift registers 600 at a time through the communication lanes of front end circuitry 320 during each transmission session. For example, for transmitting data units of the target flit that are arranged in 5 rows in FIG. 6A, 5 transmission sessions are performed.

In some embodiments, according to the first remapping scheme in FIG. 5B, at the first stage, the registers at rows 612, 614, 616, and 618 store, based on the row and lane assignments of flit protocol format 500A, data values of a particular bit position of the data units of a target flit. For example, the component register 602 is at lane 631, row 614, and thus stores a bit from data unit B64 in FIG. 5A; and component register 604 is at lane 632, row 614, and thus stores a bit from data unit B65 in FIG. 5A. Also, in some embodiments, the component registers at extra row 622 store a default data value (e.g., 0).

In some embodiments, at the second stage, the data values stored in rows 612-618 are shifted and/or bypassed in order to skip the components registers corresponding to the defective lanes (labeled with the cross marks, including lanes 632, 633, 635, and 636). In some embodiments, as the defective lanes reduce the available communication lanes for each row, a portion of the data units of the target flit is shifted out of rows 612-618 and into extra row 622. In some embodiments, the skipped registers are to be ignored during transmission, and the data values stored therein are thus irrelevant. In some embodiments, the skipped registers store a default value (e.g., 0). As a result, the data values (of a particular bit of the data units of the target flit) are rearranged from being stored corresponding to flit protocol format 500A to being stored corresponding to flit protocol format 500A.

FIG. 6B is a block diagram of a control logic 650 of the set of shift registers 600 in FIG. 6A and a component register example 660 of the set of shift registers 600 in FIG. 6A, according to various embodiments. In some embodiments, control logic 650 is incorporated in dynamic remapping circuitry 312 in FIG. 3.

In FIG. 6B, component register 660 includes a register 662, a shift multiplexer 664, a shift mask selector 665, a bypass multiplexer 666, and a bypass mask selector 667. In FIG. 6B, component register 660 also includes a data-in terminal D and a data-out terminal Q. In some embodiments, data-in terminal D is coupled to a data-out terminal of a previous-stage component register (with respect to the data shifting direction in FIG. 6A), and data-out terminal Q is coupled to a data-in terminal of a next-stage component register (with respect to the data shifting direction in FIG. 6A).

In some embodiments, register 662 includes a D type flip flop that includes a data-in terminal D′, a data-out terminal Q′, and a clock terminal coupled to a clock signal CLK. In FIG. 6B, shift multiplexer 664 is configured to selectively provide the signal at data-in terminal D or data-out terminal Q′ to data-in terminal D′ based on a control signal from shift mask selector 665; and bypass multiplexer 666 is configured to selectively provide the signal at data-in terminal D′ or data-out terminal Q′ to data-out terminal Q based on a control signal from bypass mask selector 667.

In some embodiments, control logic 650 is configured to, based on the identified defective lanes, set the patterns of shift masks smask0, smask1, smask2, smask3, smask4, and smask5, and to set the patterns of bypass masks bpmask0, bpask1, bpask2, bpask3, and bpask4. In FIG. 6B, “[n]” represents a particular lane n of the communication lanes with which the component register 660 is associated. In some embodiments, control logic 650 is further configured to control shift mask selector 665 and bypass mask selector 667 to output, based on the patterns of shift masks and the patterns of bypass masks, the suitable mask signal to respective shift multiplexer 664 and bypass multiplexer 666 for each clock cycle based on clock signal CLK.

In a non-limiting example based on the examples in FIGS. 5B and 6A, control logic 650 obtains lane defect information indicating a pattern of the defect lanes, and control logic 650 identifies a set of shift masks and a set of bypass masks associated with the pattern of the defect lanes. In this non-limiting example, the pattern of the defect lanes is {0110110000 . . . 0000}, which is a 64-bit binary number identifying the defective lanes with value 1 and functional lanes with value 0. In this non-limiting example, the set of shift masks associated with the pattern of the defect lanes includes sets of 64-bit values as presented in Table I (including the shift mask identifiers and the corresponding bitmap, where 1 represents shift and 0 represents no shift).

TABLE I

| Shift Mask Identifier | Shift Mask Bitmap |
|---|---|
| smask0 | 0000000000 . . . 0000 |
| smask1 | 0000011111 . . . 1111 |
| smask2 | 0000111111 . . . 1111 |
| smask3 | 0011111111 . . . 1111 |
| smask4 | 0111111111 . . . 1111 |
| smask5 | 1111111111 . . . 1111 |

In this non-limiting example, the set of bypass masks associated with the pattern of the defect lanes includes sets of 64-bit values as presented in Table II (including the bypass mask identifiers and the corresponding bitmap, where 1 represents bypass and 0 represents no bypass).

TABLE II

| Bypass Mask Identifier | Bypass Mask Bitmap |
|---|---|
| bpmask0 | 0000000000 . . . 0000 |
| bpmask1 | 0000010000 . . . 0000 |
| bpmask2 | 0000110000 . . . 0000 |
| bpmask3 | 0010110000 . . . 0000 |
| bpmask4 | 0110110000 . . . 0000 |

In this non-limiting example, the applicable shift mask and the applicable bypass mask are selected and updated each clock cycle, based on mask sequences as presented in Table III (including the rows and corresponding mask sequences).

TABLE III

| Row | Mask Sequence |
|---|---|
| Row 0 (row 612 | shift masks [12 smask0 (or labeled as (×12) in this disclosure), smask1, |
| in FIG. 6A) | smask2, smask3, smask4, smask0 (until reset)], and |
| | bypass masks [bpmask0 (×13), bpmask1, bpmask2, bpmask3, bpmask4 (until |
| | reset)] |
| Row 1 (row 614 | shift masks [smask0 (×8), smask1, smask2, smask3, smask4, smask5 (×4), |
| in FIG. 6A) | smask0 (until reset)], and |
| | bypass masks [bpmask0 (×9), bpmask1, bpmask2, bpmask3, bpmask4 (until |
| | reset)] |
| Row 2 (row 616 | shift masks [smask0 (×4), smask1, smask2, smask3, smask4, smask5 (×8), |
| in FIG. 6A) | smask0 (until reset)], and |
| | bypass masks [bpmask0 (×5), bpmask1, bpmask2, bpmask3, bpmask4 (until |
| | reset)] |
| Row 3 (row 618 | shift masks [smask1, smask2, smask3, smask4, smask5 (×12), smask0 (until |
| in FIG. 6A) | reset)], and |
| | bypass masks [bpmask0, bpmask1, bpmask2, bpmask3, bpmask4 (until |
| | reset)] |
| Row 4 (row 622 | shift masks [smask5 (×16), smask0 (until reset)], and |
| in FIG. 6A) | bypass masks [bpmask4 (until reset)] |

The circuit examples in FIG. 6A and FIG. 6B are merely non-limiting examples. The number of component registers and the mask patterns are to be determined based on a number of fixable defective lanes and the flit format to be transmitted. Moreover, the non-limiting examples in FIGS. 6A and 6B correspond to converting a flit from a flit protocol format to a flit reassemble format for transmission. In some embodiments, the set of shift registers 600 is applicable for converting a flit from a flit reassemble format to a flit protocol format for reception, with data shifted in a reversed data shift direction and/or proper shift masks in view of the example of FIG. 6B.

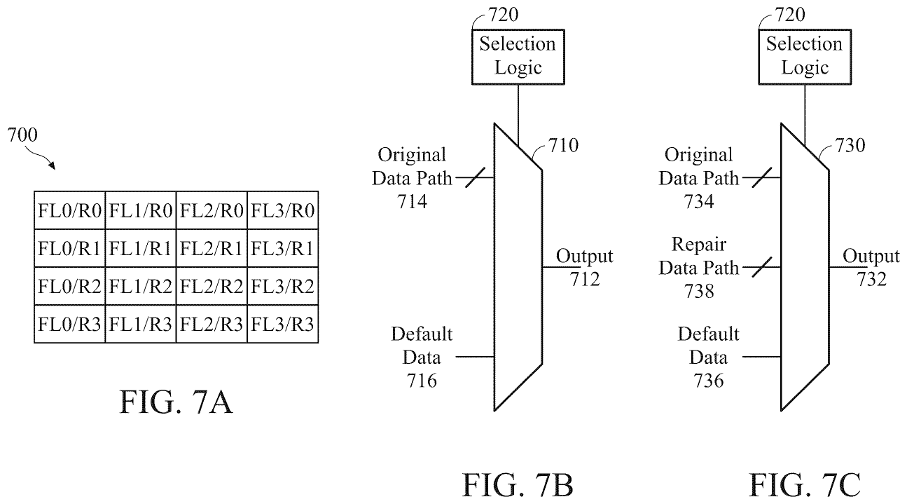

FIG. 7A is a diagram of repair registers 700 for storing data units of a target flit that correspond to the defective lanes, according to various embodiments. In some embodiments, repair registers 700 are incorporated in dynamic remapping circuitry 312 in FIG. 3, or incorporated in physical layer logic circuitry 310 in FIG. 3 and accessible by dynamic remapping circuitry 312.

In FIG. 7A, each rectangular box represents a set of repair registers for storing a data unit assigned to a defective lane at a particular row. For example, repair register FL0/R0 is for storing a data unit at a first defective lane (e.g., lane 1 in FIG. 5C), first row (e.g., row 0). Similarly, repair registers FL0/R1, FL0/R2, and FL0/R3 store data units at a first defective lane (e.g., lane 1 in FIG. 5C), second through fourth rows (e.g., rows 1-3); repair registers FL1/R0, FL1/R1, FL1/R2, and FL1/R3 store data units at a second defective lane (e.g., lane 2 in FIG. 5C), first through fourth rows (e.g., rows 0-3); repair registers FL2/R0, FL2/R1, FL2/R2, and FL2/R3 store data units at a third defective lane (e.g., lane 4 in FIG. 5C), first through fourth rows (e.g., rows 0-3); and repair registers FL3/R0, FL3/R1, FL3/R2, and FL3/R3 store data units at a fourth defective lane (e.g., lane 5 in FIG. 5C), first through fourth rows (e.g., rows 0-3). The number of repair registers 700 is determinable based on a number of communication lanes and rows for a flit, as well as a number of reparable lanes. In this non-limiting example, reserving 16 data units (e.g., bytes) of repair registers for storing data units from defective lanes, based on a flit protocol format having 64 lanes and 4 rows, is for repairing up to four defective lanes.

In this non-limiting example, based on the second remapping scheme in FIG. 5C, 20 of 64 communication lanes are designated as repair lanes and configured to transmit, in an extra row (row 0 in FIG. 5C), data units from the defective lanes in the regular rows (rows 1-4 in FIG. 5C) and stored in repair registers 700. In this non-limiting example, 20 repair lanes are used because there are 16 data units (from four rows and four defective lanes) to be transmitted in the extra row, with the possibility of all four defective lanes falling within the repair lanes. In some embodiments, the four defective lanes are configured to transmit default data (e.g., 0).

FIG. 7B is a diagram of a multiplexer example 710 that is configured to select a data path for a communication lane that is not used as a repair lane, according to various embodiments. In FIG. 7B, multiplexer 710 is configured to selectively couple a data path to an output terminal 712 for one of the communication lanes. In some embodiments, for transmitting a flit based on flit reassemble format 500C in FIG. 5C, there are 44 multiplexers based on multiplexer 710 for each of the 44 communications lanes that are not used as repair lanes. In some embodiments, a number of communication lanes not used as repair lanes is configured based on a number of defective lanes to be repairable as planned by a circuit designer.

In FIG. 7B, multiplexer 710 is configured to select the data path from a plurality of original data paths 714 and a default data 716. In some embodiments, based on transmitting the first row based on flit reassemble format 500C in FIG. 5C, multiplexer 710 is configured to receive default data 716 (e.g., 0). In some embodiments, based on transmitting the second through fifth rows based on flit reassemble format 500C in FIG. 5C, multiplexer 710 is configured to couple to respective sets of registers storing data units of the first through fourth rows in flit protocol format 500A in FIG. 5A, and thus effectively corresponding to the second through fifth rows based on flit reassemble format 500C in FIG. 5C. In some embodiments, multiplexer 710 is also configured to receive default data 716 (e.g., 0) based on the corresponding lane being a defective lane. In some embodiments, multiplexer 710 is coupled to a selection logic 720, which is configured to control the selection of various data paths. In some embodiments, selection logic 720 is part of dynamic remapping circuitry 312 in FIG. 3.

FIG. 7C is a diagram of a multiplexer example 730 that is configured to select a data path for a communication lane that is used as a repair lane, according to various embodiments. In FIG. 7C, multiplexer 730 is configured to selectively couple a data path to an output terminal 732 for one of the communication lanes configured as repair lanes. In some embodiments, for transmitting a flit based on flit reassemble format 500C in FIG. 5C, there are 20 multiplexers based on multiplexer 730 for each of the 20 communications lanes used as repair lanes. In some embodiments, multiplexer 730 is coupled to selection logic 720, which is configured to control the selection of various data paths. In some embodiments, selection logic 720 determines which 16 of the 20 repair lanes are used for repair or not based on whether there are any defective lanes within the 20 repair lanes.

In FIG. 7C, multiplexer 730 is configured to select the data path from a plurality of original data paths 734, a default data 736, and a plurality of repair data paths 738. In some embodiments, based on transmitting the first row based on flit reassemble format 500C in FIG. 5C, multiplexer 730 is configured to couple to respective registers storing data units of the defective lanes in registers 700 in FIG. 7A. In some embodiments, based on transmitting the second through fifth rows based on flit reassemble format 500C in FIG. 5C, multiplexer 730 is configured to couple to respective registers storing data units of the first through fourth rows in flit protocol format 500A in FIG. 5A, and thus effectively corresponding to the second through fifth rows based on flit reassemble format 500C in FIG. 5C. In some embodiments, multiplexer 730 is also configured to receive default data 736 (e.g., 0) based on whether the corresponding lane is a defective lane or not used for repair during the transmission of the first row.

In some embodiments, original data paths 714 in FIG. 7B or original data paths 734 in FIG. 7C include four different data paths corresponding to four rows (e.g., rows 0-3 in FIG. 5A or rows 1-4 in FIG. 5C). In some embodiments, repair data paths 738 in FIG. 7C include five different data paths corresponding to up to five different sets of registers from repair registers 700. In some embodiments, each set of registers for storing a data unit from a particular defective lane and a particular row is coupled to five different multiplexers of the 20 multiplexers for the 20 repair lanes in order to provide alternative data paths in a case where up to four of the 20 repair lanes are defective.

The circuit examples in FIGS. 7A-7C are merely non-limiting examples. The number of repair registers and the number and the types of the multiplexers are to be determined based on a number of fixable defective lanes and the flit format to be transmitted. Moreover, the non-limiting examples illustrated in FIGS. 7A-7C correspond to converting a flit from a flit protocol format to a flit reassemble format for transmission. In some embodiments, counterpart multiplexers of multiplexer 710 and multiplexer 730, with reversed direction of signals, are applicable for passing the received data units based on flit resemble format 500C to repair registers 700 (e.g., from the first row in FIG. 5C) and a table based on flit protocol format 500A (from the second through fifth rows in FIG. 5C), and then moving the data units in the repair registers 700 to appropriate position in the table based on flit protocol format 500A to restore the data units corresponding to the defective lanes.

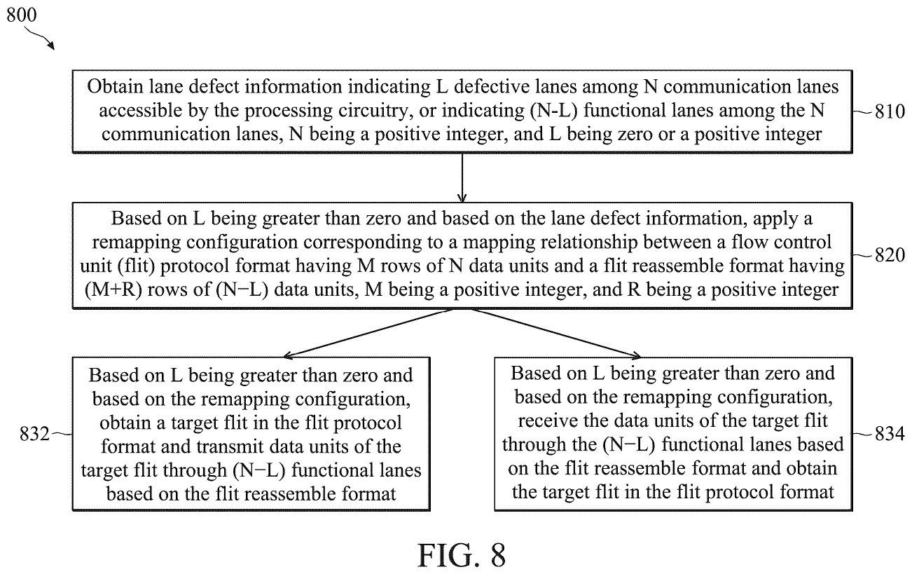

FIG. 8 is a flowchart of a method 800 of communication, in accordance with some embodiments. In some embodiments, various operations of method 800 are performed by processing circuitry (e.g., a semiconductor die or a semiconductor circuit block) of a semiconductor device (e.g., an IC package). In some embodiments, the processing circuitry corresponds to physical layer logic circuitry 310 in FIG. 3, circuitry examples in FIGS. 6A-6B, and/or circuitry examples in FIGS. 7A-7C. As in FIG. 8, method 800 includes blocks 810-834.

At block 810, the processing circuitry obtains lane defect information indicating L defective lanes among N communication lanes accessible by the processing circuitry, or indicating (N−L) functional lanes among the N communication lanes. In some embodiments, N is a positive integer, and L is zero or a positive integer. In some embodiments, the processing circuitry obtains the lane defect information by generating the lane defect information (e.g., by lane defect detection circuitry 314), or by receiving the lane defect information from another processing circuitry (e.g., another semiconductor die or another circuit block) of the semiconductor device.

At block 820, based on L being greater than zero and based on the lane defect information, the processing circuitry applies a remapping configuration corresponding to a mapping relationship between a flit protocol format having M rows of N data units and a flit reassemble format having (M+R) rows of (N−L) data units. In some embodiments, M is a positive integer, and R is a positive integer.

In some embodiments according to a first remapping scheme in FIGS. 5B and 6A-6B, the mapping relationship corresponds to sequentially mapping N data units per row, M rows in total, in the flit protocol format to (N−L) data units per row, (M+R) rows in total, in the flit reassemble format. In some embodiments according to a second remapping scheme in FIGS. 5C and 7A-7C, the mapping relationship corresponds to mapping (N−L) data units per row, M rows in total, in the flit protocol format that correspond to the (N−L) functional lanes to (N−L) data units per row, M rows in total, in the flit reassemble format based on original row and lane assignments in the flit protocol format; and mapping M×L data units in the flit protocol format that corresponds to the L defective lanes to up to R extra rows in the flit reassemble format.

At block 832, for transmitting one or more target flits, based on L being greater than zero and based on the remapping configuration, the processing circuitry obtains a target flit in the flit protocol format and transmits data units of the target flit through (N−L) functional lanes based on the flit reassemble format.

At block 834, for receiving the one or more target flits, based on L being greater than zero and based on the remapping configuration, the processing circuitry receives the data units of the target flit through the (N−L) functional lanes based on the flit reassemble format and obtains the target flit in the flit protocol format.

In some embodiments, each one of the data units corresponds to a byte. In some embodiments, N ranges from 32 to 128, M ranges from 1 to 8, and R ranges from 1 to 4. In some embodiments, the target flit includes 256 bytes, N is 64, M is 4, and R is 1.

In some embodiments, based on stages 424, 430, and 442 in FIG. 4 from the perspective of first processing circuitry 402, method 800 further includes receiving one or more test flits through the N communication lanes from another processing circuitry, and identifying the L defective lanes or the (N−L) functional lanes among the N communication lanes based on reception of the one or more test flits. In some embodiments, method 800 further includes transmitting, through a control interface, the lane defect information to the other processing circuitry, the lane defect information indicating the L defective lanes or the (N−L) functional lanes.

In some embodiments, based on stages 424 and 442 in FIG. 4 from the perspective of second processing circuitry 406, method 800 further includes transmitting one or more test flits through the N communication lanes to another processing circuitry. In some embodiments, method 800 further includes receiving, through a control interface, the lane defect information from the other processing circuitry, the lane defect information indicating the L defective lanes or the (N−L) functional lanes.

In some aspects, a semiconductor device includes a processing circuitry and N signal paths corresponding to N communication lanes, N being a positive integer. In some aspects, the processing circuitry is coupled to the N signal paths, and the processing circuitry is configured to obtain lane defect information indicating L defective lanes among the N communication lanes, or indicating (N−L) functional lanes among the N communication lanes, L being zero or a positive integer. The processing circuitry is configured to, based on L being greater than zero and based on the lane defect information, apply a remapping configuration corresponding to a mapping relationship between a flow control unit (flit) protocol format having M rows of N data units and a flit reassemble format having (M+R) rows of (N−L) data units, M being a positive integer, and R being a positive integer. The processing circuitry is configured to, based on L being greater than zero and based on the remapping configuration, obtain a target flit in the flit protocol format and transmit data units of the target flit through (N−L) functional lanes based on the flit reassemble format, or receive the data units of the target flit through the (N−L) functional lanes based on the flit reassemble format and obtain the target flit in the flit protocol format.

In some aspects, a method of communication by a processing circuitry of a semiconductor device includes obtaining lane defect information indicating L defective lanes among N communication lanes accessible by the processing circuitry, or indicating (N−L) functional lanes among the N communication lanes, N being a positive integer, and L being zero or a positive integer. The method includes, based on L being greater than zero and based on the lane defect information, applying a remapping configuration corresponding to a mapping relationship between a flow control unit (flit) protocol format having M rows of N data units and a flit reassemble format having (M+R) rows of (N−L) data units, M being a positive integer, and R being a positive integer. The method includes, based on L being greater than zero and based on the remapping configuration, obtaining a target flit in the flit protocol format and transmitting data units of the target flit through (N−L) functional lanes based on the flit reassemble format; or receiving the data units of the target flit through the (N−L) functional lanes based on the flit reassemble format and obtaining the target flit in the flit protocol format.

In some aspects, a semiconductor device includes a dynamic remapping circuitry, a protocol circuitry, and a front end circuitry configured to transmit or receive data units of a target flow control unit (flit) through N communication lanes, N being a positive integer. In some aspects, the dynamic remapping circuitry is coupled to the protocol circuitry and the front end circuitry, and the dynamic remapping circuitry is configured to obtain lane defect information indicating L defective lanes among the N communication lanes, or indicating (N−L) functional lanes among the N communication lanes, L being zero or a positive integer. The dynamic remapping circuitry is configured to, based on L being greater than zero and based on the lane defect information, apply a remapping configuration corresponding to a mapping relationship between a flit protocol format having M rows of N data units and a flit reassemble format having (M+R) rows of (N−L) data units, M being a positive integer, and R being a positive integer. dynamic remapping circuitry is configured to, based on L being greater than zero and based on the remapping configuration, receive the target flit in the flit protocol format from the protocol circuitry and transmit the data units of the target flit through the (N−L) functional lanes based on the flit reassemble format; or receive the data units of the target flit through the (N−L) functional lanes based on the flit reassemble format and transmit the target flit in the flit protocol format to the protocol circuitry.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A semiconductor device, comprising:
a processing circuitry; and
N signal paths corresponding to N communication lanes, N being a positive integer,
wherein the processing circuitry is coupled to the N signal paths, and the processing circuitry is configured to:
obtain lane defect information indicating L defective lanes among the N communication lanes, or indicating (N−L) functional lanes among the N communication lanes, L being zero or a positive integer;
based on L being greater than zero and based on the lane defect information, apply a remapping configuration corresponding to a mapping relationship between a flow control unit (flit) protocol format having M rows of N data units and a flit reassemble format having (M+R) rows of (N−L) data units, M being a positive integer, and R being a positive integer;
based on L being greater than zero and based on the remapping configuration:
obtain a target flit in the flit protocol format and transmit data units of the target flit through (N−L) functional lanes based on the flit reassemble format; or
receive the data units of the target flit through the (N−L) functional lanes based on the flit reassemble format and obtain the target flit in the flit protocol format.

2. The semiconductor device of claim 1, wherein the processing circuitry is configured to:
sequentially map N data units per row, M rows in total, in the flit protocol format to (N−L) data units per row, (M+R) rows in total, in the flit reassemble format.

3. The semiconductor device of claim 1, wherein the processing circuitry is configured to:
map (N−L) data units per row, M rows in total, in the flit protocol format that correspond to the (N−L) functional lanes to (N−L) data units per row, M rows in total, in the flit reassemble format based on original row and lane assignments in the flit protocol format; and
map M×L data units in the flit protocol format that correspond to the L defective lanes to up to R extra rows in the flit reassemble format.

4. The semiconductor device of claim 1, wherein the processing circuitry is further configured to:
receive one or more test flits through the N communication lanes from another processing circuitry;
identify the L defective lanes or the (N−L) functional lanes among the N communication lanes based on reception of the one or more test flits; and
transmit, through a control interface, the lane defect information to the other processing circuitry, the lane defect information indicating the L defective lanes or the (N−L) functional lanes.

5. The semiconductor device of claim 1, wherein the processing circuitry is further configured to:
transmit one or more test flits through the N communication lanes to another processing circuitry; and
receive, through a control interface, the lane defect information from the other processing circuitry, the lane defect information indicating the L defective lanes or the (N−L) functional lanes.

6. The semiconductor device of claim 1, wherein
each one of the data units corresponds to a byte,
N ranges from 32 to 128,
M ranges from 1 to 8, and
R ranges from 1 to 4.

7. The semiconductor device of claim 1, wherein
each one of the data units corresponds to a byte,
the target flit includes 256 bytes,
N is 64,
M is 4, and
R is 1.

8. A method of communication by a processing circuitry of a semiconductor device, comprising:
obtaining lane defect information indicating L defective lanes among N communication lanes accessible by the processing circuitry, or indicating (N−L) functional lanes among the N communication lanes, N being a positive integer, and L being zero or a positive integer,
based on L being greater than zero and based on the lane defect information, applying a remapping configuration corresponding to a mapping relationship between a flow control unit (flit) protocol format having M rows of N data units and a flit reassemble format having (M+R) rows of (N−L) data units, M being a positive integer, and R being a positive integer; and
based on L being greater than zero and based on the remapping configuration:
obtaining a target flit in the flit protocol format and transmitting data units of the target flit through (N−L) functional lanes based on the flit reassemble format; or
receiving the data units of the target flit through the (N−L) functional lanes based on the flit reassemble format and obtaining the target flit in the flit protocol format.

9. The method of claim 8, wherein the mapping relationship corresponds to:
sequentially mapping N data units per row, M rows in total, in the flit protocol format to (N−L) data units per row, (M+R) rows in total, in the flit reassemble format.

10. The method of claim 8, wherein the mapping relationship corresponds to:
mapping (N−L) data units per row, M rows in total, in the flit protocol format that correspond to the (N−L) functional lanes to (N−L) data units per row, M rows in total, in the flit reassemble format based on original row and lane assignments in the flit protocol format; and
mapping M×L data units in the flit protocol format that correspond to the L defective lanes to up to R extra rows in the flit reassemble format.

11. The method of claim 8, further comprising:
receiving one or more test flits through the N communication lanes from another processing circuitry;
identifying the L defective lanes or the (N−L) functional lanes among the N communication lanes based on reception of the one or more test flits; and
transmitting, through a control interface, the lane defect information to the other processing circuitry, the lane defect information indicating the L defective lanes or the (N−L) functional lanes.

12. The method of claim 8, further comprising:
transmitting one or more test flits through the N communication lanes to another processing circuitry; and
receiving, through a control interface, the lane defect information from the other processing circuitry, the lane defect information indicating the L defective lanes or the (N−L) functional lanes.

13. The method of claim 8, wherein
each one of the data units corresponds to a byte,
N ranges from 32 to 128,
M ranges from 1 to 8, and
R ranges from 1 to 4.

14. The method of claim 8, wherein
each one of the data units corresponds to a byte,
the target flit includes 256 bytes,
N is 64,
M is 4, and
R is 1.

15. A semiconductor device, comprising:
a dynamic remapping circuitry;
a protocol circuitry; and
a front end circuitry configured to transmit or receive data units of a target flow control unit (flit) through N communication lanes, N being a positive integer,
wherein the dynamic remapping circuitry is coupled to the protocol circuitry and the front end circuitry, and the dynamic remapping circuitry is configured to:
obtain lane defect information indicating L defective lanes among the N communication lanes, or indicating (N−L) functional lanes among the N communication lanes, L being zero or a positive integer;
based on L being greater than zero and based on the lane defect information, apply a remapping configuration corresponding to a mapping relationship between a flit protocol format having M rows of N data units and a flit reassemble format having (M+R) rows of (N−L) data units, M being a positive integer, and R being a positive integer;
based on L being greater than zero and based on the remapping configuration:
receive the target flit in the flit protocol format from the protocol circuitry and transmit the data units of the target flit through the (N−L) functional lanes based on the flit reassemble format; or
receive the data units of the target flit through the (N−L) functional lanes based on the flit reassemble format and transmit the target flit in the flit protocol format to the protocol circuitry.

16. The semiconductor device of claim 15, wherein the dynamic remapping circuitry is configured to:
sequentially map N data units per row, M rows in total, in the flit protocol format to (N−L) data units per row, (M+R) rows in total, in the flit reassemble format.

17. The semiconductor device of claim 15, wherein the dynamic remapping circuitry is configured to:
map (N−L) data units per row, M rows in total, in the flit protocol format that correspond to the (N−L) functional lanes to (N−L) data units per row, M rows in total, in the flit reassemble format based on original row and lane assignments in the flit protocol format; and
map M×L data units in the flit protocol format that correspond to the L defective lanes to up to R extra rows in the flit reassemble format.

18. The semiconductor device of claim 15, further comprising:
a control interface; and
a lane defect detection circuitry configured to:
receive one or more test flits through the N communication lanes from another processing circuitry;
identify the L defective lanes or the (N−L) functional lanes among the N communication lanes based on reception of the one or more test flits; and
transmit, through the control interface, the lane defect information to the other processing circuitry, the lane defect information indicating the L defective lanes or the (N−L) functional lanes.

19. The semiconductor device of claim 15, further comprising:
a control interface; and
a lane defect detection circuitry configured to:
transmit one or more test flits through the N communication lanes to another processing circuitry; and
receive, through the control interface, the lane defect information from the other processing circuitry, the lane defect information indicating the L defective lanes or the (N−L) functional lanes.

20. The semiconductor device of claim 15, wherein
each one of the data units corresponds to a byte,
N ranges from 32 to 128,
M ranges from 1 to 8, and
R ranges from 1 to 4.
